(19) United States
(12) Patent Application Publication
(10) Pub. No.: US 2025/0127021 A1
(43) Pub. Date: Apr. 17, 2025

(54) DISPLAY DEVICE

(71) Applicant: Samsung Display Co., Ltd., Yongin-Si (KR)

(72) Inventors: JONGHO SON, Yongin-si (KR); OHJEONG KWON, Yongin-si (KR); DAEWON KIM, Yongin-si (KR); TAEHO KIM, Yongin-si (KR); MIHWA LEE, Yongin-si (KR); SUNGGYU JANG, Yongin-si (KR)

(21) Appl. No.: 18/909,714

(22) Filed: Oct. 8, 2024

(30) Foreign Application Priority Data
Oct. 12, 2023 (KR) 10-2023-0136294

(51) Int. Cl. H10K 59/80; H10K 59/122

(52) U.S. Cl. CPC H10K 59/879; H10K 59/122

(57) ABSTRACT

A display device includes a thin film transistor, a pixel electrode including a first portion, a second portion, and a third portion, the third portion positioned outside the first portion and the second portion, a pixel defining layer on the pixel electrode and defining a first pixel opening above the first portion of the pixel electrode and a second pixel opening above the second portion of the pixel electrode, an emission layer above the first pixel opening and the second pixel opening, a first refractive layer on the pixel defining layer and defining a first opening above the first pixel opening and a second opening overlapping the second pixel opening, and a second refractive layer on the first refractive layer, filling the first opening and the second opening of the first refractive layer, and having a refractive index greater than a refractive index of the first refractive layer.

This application claims priority to Korean Patent Application No. 10-2023-0136294 filed on Oct. 12, 2023, and all the benefits accruing therefrom under 35 U.S.C. § 119, which is hereby incorporated by reference for all purposes.

### BACKGROUND

### 1. Field

Embodiments relate to a display device.

### 2. Description of the Related Art

Flat panel display devices are replacing cathode ray tube display devices as display devices due to their lightweight and thin characteristics. As representative examples of such flat panel display devices, there are liquid crystal display devices and organic light emitting diode display devices.

The display device may display an image using a light emitting element. In the display device, it is desirable for light generated from the light emitting element to be directed to an area in front of the display device. However, the light generated from the light emitting element travels in multiple directions including the front direction and side directions. Accordingly, luminance in the front direction may be lowered.

### SUMMARY

Embodiments provide a display device with improved display quality.

Additional features of the inventive concepts will be set forth in the description which follows, and in part will be apparent from the description, or may be learned by practice of the inventive concepts.

A display device according to an embodiment may include a thin film transistor, a pixel electrode electrically connected to the thin film transistor and including a first portion, a second portion, and a third portion, the third portion being positioned outside the first portion and the second portion, a pixel defining layer disposed on the pixel electrode and defining a first pixel opening above the first portion of the pixel electrode and a second pixel opening above the second portion of the pixel electrode, an emission layer disposed on the pixel electrode and overlapping the first pixel opening and the second pixel opening, a first refractive layer disposed on the pixel defining layer and defining a first opening above the first pixel opening and a second opening above the second pixel opening, and a second refractive layer disposed on the first refractive layer, filling the first opening and the second opening of the first refractive layer, and having a refractive index greater than a refractive index of the first refractive layer.

In an embodiment, the first portion, the second portion, and the third portion of the pixel electrode may be integrated.

In an embodiment, the first portion of the pixel electrode and the second portion of the pixel electrode may be spaced apart from each other. A portion of the third portion of the pixel electrode may be positioned between the first portion of the pixel electrode and the second portion of the pixel electrode.

In an embodiment, the first pixel opening and the second pixel opening may be spaced apart from each other. The first opening and the second opening may be spaced apart from each other.

In an embodiment, the first refractive layer between the first opening and the second opening may have a trapezoidal cross-sectional shape.

In an embodiment, the first opening and the second opening may have side walls that are inclined with respect to a lower surface of the first refractive layer.

In an embodiment, the first refractive layer may have a lower surface facing the pixel defining layer, an upper surface opposite to the lower surface, a first refractive side wall defining the first opening, and a second refractive side wall defining the second opening. A first upper edge of the first refractive layer, defined as an edge where the upper surface of the first refractive layer adjoins the first refractive side wall of the first opening, may surround the first pixel opening in a plan view. A second upper edge of the first refractive layer, defined as an edge where the upper surface of the first refractive layer adjoins the second refractive side wall of the second opening, may surround the second pixel opening in a plan view.

In an embodiment, an angle between the lower surface of the first refractive layer and the first refractive side wall of the first opening may be in a range of about 30 degrees to about 70 degrees.

In an embodiment, the emission layer may overlap all of the first portion of the pixel electrode, the second portion of the pixel electrode, and the third portion of the pixel electrode.

In an embodiment, the first portion of the pixel electrode and the second portion of the pixel electrode may adjoin each other.

In an embodiment, the first pixel opening and the second pixel opening may adjoin with each other. The first opening and the second opening may be integrated.

In an embodiment, the first refractive layer may have a lower surface facing the pixel defining layer, an upper surface opposite to the lower surface, and a side wall defining the first opening and the second opening. An upper edge of the first refractive layer, defined as an edge where the upper surface of the first refractive layer adjoins the side wall of the first refractive layer, may surround the first pixel opening and the second pixel opening in a plan view.

In an embodiment, in a plan view, a size of the first opening may be greater than a size of the first pixel opening. A size of the second opening may be greater than a size of the second pixel opening.

In an embodiment, the display device may further include an encapsulation layer disposed on the pixel defining layer and the emission layer and a touch electrode layer disposed between the encapsulation layer and the first refractive layer.

A display device according to an embodiment may include a thin film transistor, a pixel electrode electrically connected to the thin film transistor and including a first portion, a second portion positioned outside the first portion, and a third portion positioned outside the second portion, a pixel defining layer disposed on the pixel electrode and defining a pixel opening above the second portion of the pixel electrode, the pixel opening having a ring shape in a plan view, an emission layer disposed on the pixel electrode and overlapping the pixel opening, a first refractive layer disposed on the pixel defining layer and defining an opening above the pixel opening, the opening having a ring shape in a plan view, and a second refractive layer disposed on the first refractive layer, filling the opening of the first refractive layer, and having a refractive index greater than a refractive index of the first refractive layer.

In an embodiment, the first refractive layer may include a mesh portion positioned outside the second portion of the pixel electrode in a plan view and an island portion spaced apart from the mesh portion and positioned on the first portion of the pixel electrode in a plan view.

In an embodiment, the island portion of the first refractive layer may have a trapezoidal cross-sectional shape.

In an embodiment, the mesh portion of the first refractive layer may have a mesh side wall facing the island portion of the first refractive layer. The island portion of the first refractive layer may have an island side wall facing the mesh portion of the first refractive layer. The opening of the first refractive layer may be defined by the mesh side wall of the mesh portion and the island side wall of the island portion.

In an embodiment, an upper edge of the mesh portion of the first refractive layer, defined as an edge where the upper surface of the mesh portion adjoins the mesh side wall of the mesh portion, may surround the pixel opening in a plan view.

In an embodiment, the emission layer may overlap all of the first portion of the pixel electrode, the second portion of the pixel electrode, and the third portion of the pixel electrode.

According to embodiments, a front luminance of the display device may be improved, and a display quality of the display device may be improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to an embodiment.

FIG. 2 is a plan view illustrating a pixel unit included in the display device of FIG. 1.

FIGS. 3 to 5 are plan views illustrating a pixel according to an embodiment.

FIG. 6 is a cross-sectional view taken along a line I-I′ of FIG. 3.

FIG. 7 is a plan view illustrating a pixel according to an embodiment.

FIG. 8 is a cross-sectional view taken along a line II-II′ of FIG. 7.

FIG. 9 is a plan view illustrating a pixel according to a comparative example.

FIGS. 10 to 12 are plan views illustrating a pixel according to an embodiment.

FIGS. 13 to 15 are plan views illustrating a pixel according to an embodiment.

FIG. 16 is a cross-sectional view taken along a line III-III′ of FIG. 13.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Illustrative, non-limiting embodiments will be more clearly understood from the following detailed description in conjunction with the accompanying drawings.

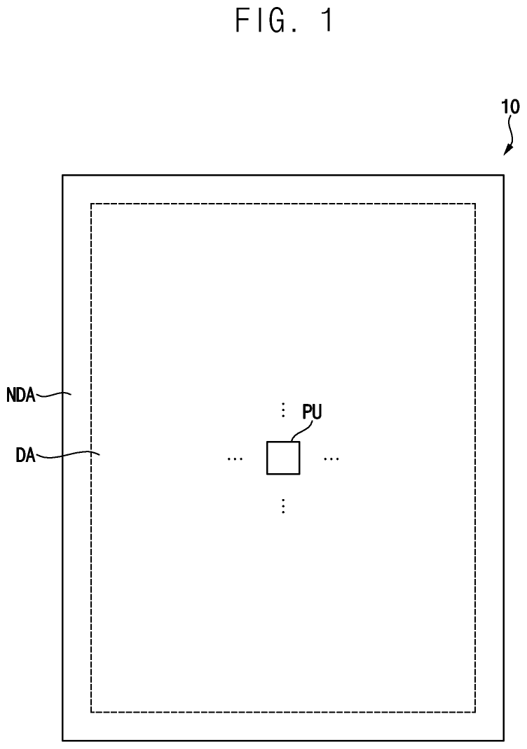

FIG. 1 is a plan view illustrating a display device according to an embodiment.

Referring to FIG. 1, a display device 10 according to an embodiment may include a display area DA and a non-display area NDA. An image may be displayed in the display area DA. A plurality of pixel units PU may be disposed in the display area DA. For example, the pixel units PU may be arranged in a matrix form along a first direction and a second direction crossing the first direction.

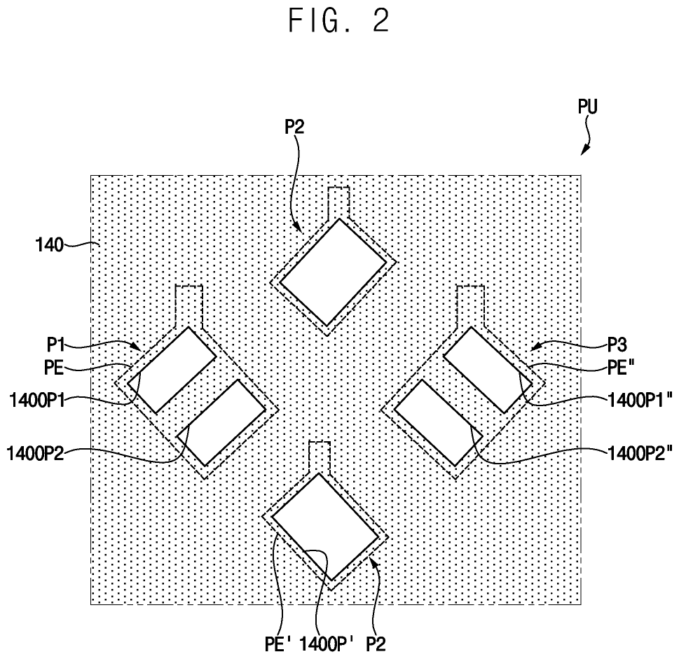

Each of the pixel units PU may include a plurality of pixels (e.g., first to third pixels P1, P2, and P3 in FIG. 2) emitting light of different colors. Each of the pixels may include at least one thin film transistor and a light emitting element. The thin film transistor may generate a driving current and provide the generated driving current to the light emitting element. The light emitting element may emit light based on the driving current. For example, the light emitting element may include an organic light emitting diode, an inorganic light emitting diode, a quantum dot light emitting diode, or the like. Light emitted from each of the pixels PX may be combined to generate the image.

The non-display area NDA may be positioned around the display area DA. For example, the non-display area NDA may surround the display area DA in a plan view. A driver providing a driving signal to the display area DA may be disposed in the non-display area NDA. The driving signal may include various signals for driving the pixels such as a driving voltage, a gate signal, a data signal, or the like.

FIG. 2 is a plan view illustrating a pixel unit included in the display device of FIG. 1.

Referring to FIGS. 1 and 2, in an embodiment, each of the pixel units PU may include a plurality of pixels emitting light of different colors. For example, each of the pixel units PU may include a first pixel P1 emitting red light, a second pixel P2 emitting green light, and a third pixel P3 emitting blue light. As illustrated in FIG. 2, each of the pixel units PU may include two second pixels P2 emitting green light. FIG. 2 illustrates that one first pixel P1, two second pixels P2, and one third pixel P3 constituting each of the pixel units PU are arranged in a PENTILE™ configuration, but this is an example, and embodiments are not limited thereto. For example, the first to third pixels P1, P2, and P3 constituting each of the pixel units PU may be arranged in various configurations, such as a stripe configuration or the like. In addition, the number or shape of the first to third pixels P1, P2, and P3 constituting each of the pixel units PU may be changed in various ways.

The first pixel P1 may include at least one thin film transistor and a first light emitting element. The first light emitting element may be electrically connected to the thin film transistor, and may emit red light. The first light emitting element may include a first pixel electrode PE, a first emission layer, and a common electrode. The first emission layer may include a light emitting material emitting red light.

The second pixel P2 may include at least one thin film transistor and a second light emitting element. The second light emitting element may be electrically connected to the thin film transistor, and may emit green light. The second light emitting element may include a second pixel electrode PE′, a second emission layer, and a common electrode. The second emission layer may include a light emitting material emitting green light.

The third pixel P3 may include at least one thin film transistor and a third light emitting element. The third light emitting element may be electrically connected to the thin film transistor, and may emit blue light. The third light emitting element may include a third pixel electrode PE″, a third emission layer, and a common electrode. The third emission layer may include a light emitting material emitting blue light.

A pixel defining layer 140 may be disposed on the first pixel electrode PE, the second pixel electrode PE′, and the third pixel electrode PE″. The pixel defining layer 140 may cover a portion of the first pixel electrode PE, a portion of the second pixel electrode PE′, and a portion of the third pixel electrode PE″.

The pixel defining layer 140 may define pixel openings respectively corresponding to the first pixel electrode PE, the second pixel electrode PE′, and the third pixel electrode PE″. Two or more of the pixel openings may correspond to at least one of the first pixel electrode PE, the second pixel electrode PE′, and the third pixel electrode PE″. For example, FIG. 2 illustrates that two pixel openings 140OP1 and 140OP2 correspond to one first pixel electrode PE′, one pixel opening 140OP′ corresponds to one second pixel electrode PE′, and two pixel openings 140OP1″ and 140OP2″ correspond to one third pixel electrode PE″, but this is an example, and embodiments are not limited thereto. For example, two or more of the pixel openings may correspond to each of the first pixel electrode PE, the second pixel electrode PE′, and the third pixel electrode PE″.

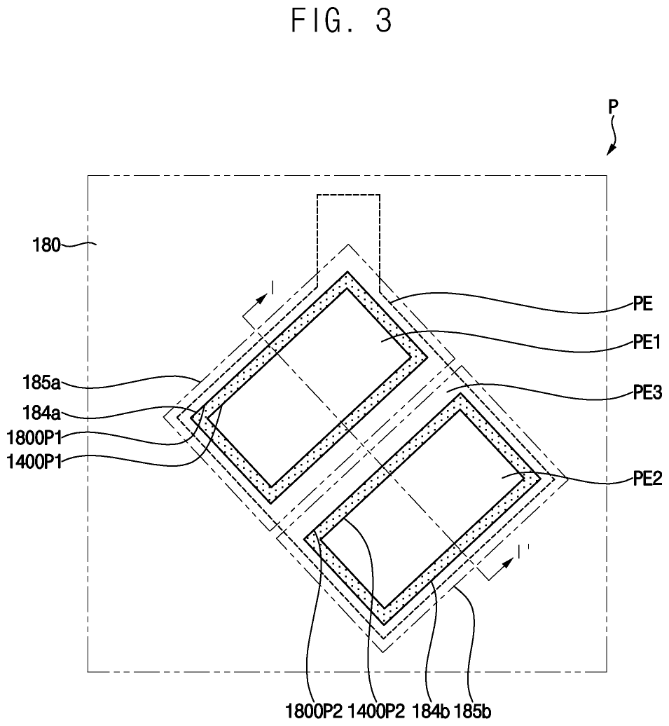

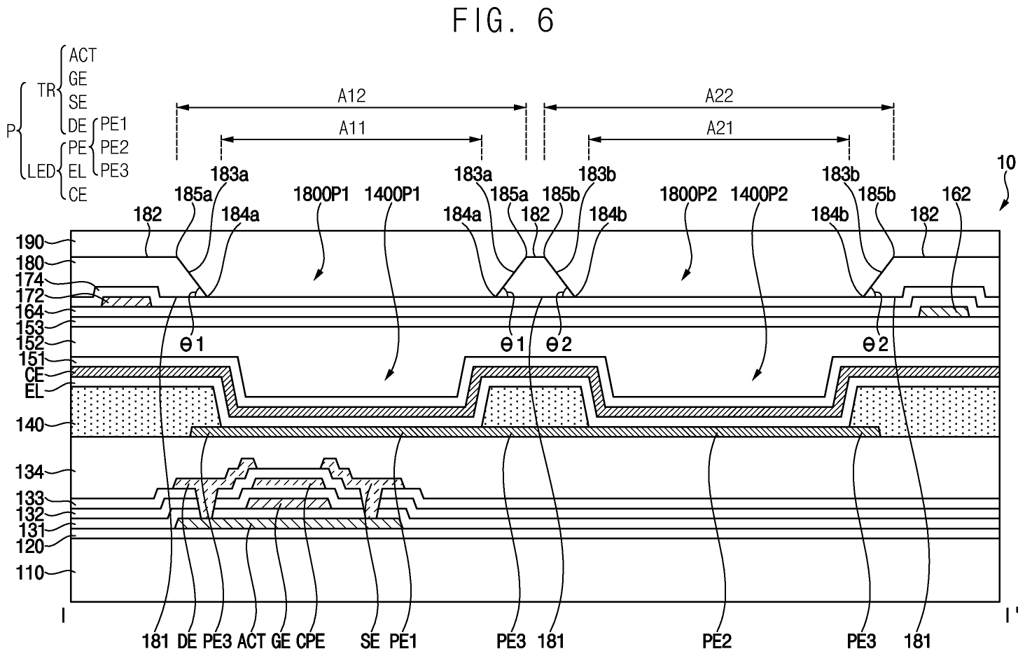

FIGS. 3 to 5 are plan views illustrating a pixel according to an embodiment. FIG. 6 is a cross-sectional view taken along a line I-I′ of FIG. 3.

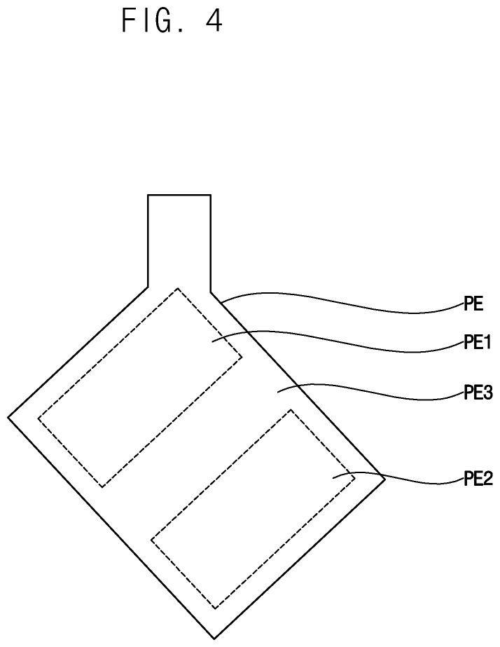

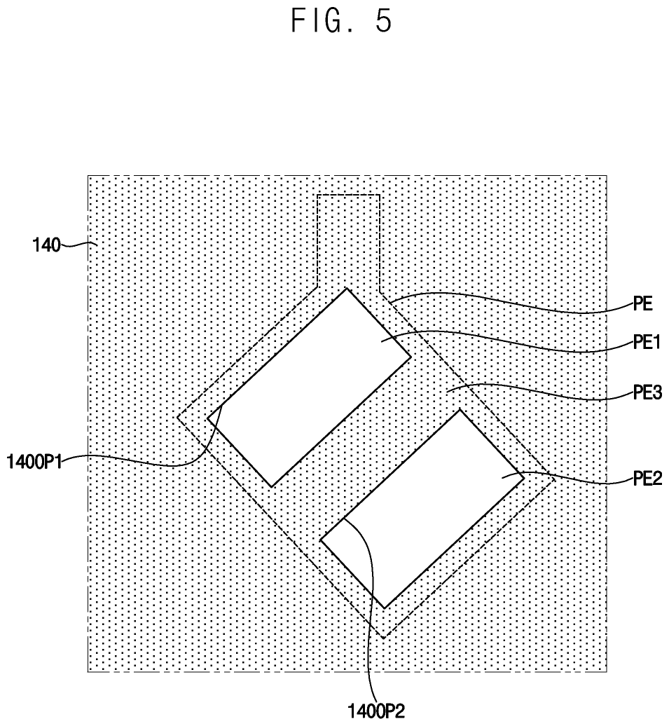

For example, a pixel P illustrated in FIG. 3 may be one of the first to third pixels P1, P2, and P3 illustrated in FIG. 2. FIG. 4 is a plan view illustrating the pixel electrode PE included in the pixel P of FIG. 3, FIG. 5 is a plan view further illustrating the pixel defining layer 140 in FIG. 4, and FIG. 3 is a plan view further illustrating a first refractive layer 180 in FIG. 5.

Referring to FIGS. 3 to 6, in an embodiment, the display device 10 may include a substrate 110, a buffer layer 120, the pixels P, the pixel defining layer 140, an encapsulation layer, a touch sensing layer, the first refractive layer 180, and a second refractive layer 190. Each of the pixels P may include the thin film transistor TR and the light emitting element LED.

The substrate 110 may be an insulating substrate formed of a transparent material or a non-transparent material. In an embodiment, the substrate 110 may include a plastic. In this case, the display device 10 may be a flexible display device. In another embodiment, the substrate 110 may include a glass. In this case, the display device 10 may be a rigid display device.

The buffer layer 120 may be disposed on the substrate 110. The buffer layer 120 may prevent or reduce impurities such as oxygen or moisture from penetrating into an upper portion of the substrate 110 through the substrate 110. The buffer layer 120 may include an inorganic material such as a silicon compound, a metal oxide, or the like. For example, the buffer layer 120 may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These can be used alone or in a combination. The buffer layer 120 may have a single-layered structure or a multi-layered structure including a plurality of insulating layers.

The thin film transistor TR may be disposed on the buffer layer 120. The thin film transistor TR may include an active layer ACT, a gate electrode GE, a source electrode SE, and a drain electrode DE.

The active layer ACT may be disposed on the buffer layer 120. The active layer ACT may include an oxide semiconductor, a silicon semiconductor, an organic semiconductor, or the like. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include an amorphous silicon, a polycrystalline silicon, or the like. The active layer ACT may include a source area, a drain area, and a channel area positioned between the source area and the drain area.

A first insulating layer 131 may be disposed on the active layer ACT. The first insulating layer 131 may cover the active layer ACT on the buffer layer 120. The first insulating layer 131 may include an inorganic insulating material.

The gate electrode GE may be disposed on the first insulating layer 131. The gate electrode GE may overlap the channel area of the active layer ACT. The gate electrode GE may include a conductive material such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These can be used alone or in a combination. The gate electrode GE may have a single-layered structure or a multi-layered structure including a plurality of conductive layers.

A second insulating layer 132 may be disposed on the gate electrode GE. The second insulating layer 132 may cover the gate electrode GE on the first insulating layer 131. The second insulating layer 132 may include an inorganic insulating material.

A capacitor electrode CPE may be disposed on the second insulating layer 132. The capacitor electrode CPE may overlap the gate electrode GE. The gate electrode GE, the second insulating layer 132, and the capacitor electrode CPE may constitute a capacitor.

A third insulating layer 133 may be disposed on the capacitor electrode CPE. The third insulating layer 133 may cover the capacitor electrode CPE on the second insulating layer 132. The third insulating layer 133 may include an inorganic insulating material.

The source electrode SE and the drain electrode DE may be disposed on the third insulating layer 133. The source electrode SE and the drain electrode DE may be connected to the source area and the drain area of the active layer ACT, respectively. Each of the source electrode SE and the drain electrode DE may include a conductive material.

A fourth insulating layer 134 may be disposed on the source electrode SE and the drain electrode DE. The fourth insulating layer 134 may include an organic insulating material. For example, the fourth insulating layer 134 may include photoresist, polyacryl-based resin, polyimide-based resin, polyamide-based resin, siloxane-based resin, acryl-based resin, epoxy-based resin, or the like. These can be used alone or in a combination thereof.

The pixel electrode PE may be disposed on the fourth insulating layer 134. The pixel electrode PE may include a conductive material. The pixel electrode PE may have a single-layered structure or a multi-layered structure including a plurality of conductive layers.

As illustrated in FIG. 4, the pixel electrode PE may include a first portion PE1, a second portion PE2, and a third portion PE3. The first portion PE1 and the second portion PE2 may be spaced apart from each other. The third portion PE3 may surround each of the first portion PE1 and the second portion PE2 in a plan view. That is, a portion of the third portion PE3 may be positioned between the first portion PE1 and the second portion PE2. The first to third portions PE1, PE2, and PE3 of the pixel electrode PE may be integrally provided.

In an embodiment, the pixel electrode PE may include a contact portion protruding in one direction (e.g., an upper direction in FIG. 4). For example, the contact portion may be a portion of the third portion PE3. Although not illustrated in the drawing, the contact portion of the pixel electrode PE may be connected to the drain electrode DE through a contact hole formed in the fourth insulating layer 134. Accordingly, the pixel electrode PE may be electrically connected to the thin film transistor TR.

The pixel defining layer 140 may be disposed on the pixel electrode PE. The pixel defining layer 140 may include an organic insulating material. The pixel defining layer 140 may define a first pixel opening 140OP1 above the first portion PE1 of the pixel electrode PE and a second pixel opening 140OP2 above the second portion PE2 of the pixel electrode PE. In a plan view, the first pixel opening 140OP1 and the second pixel opening 140OP2 may be spaced apart from each other. The pixel defining layer 140 may cover the third portion PE3 of the pixel electrode PE.

The pixel defining layer 140 may have a first PDL side wall defining the first pixel opening 140OP1 and a second PDL side wall defining the second pixel opening 140OP2. A first edge of the pixel defining layer 140, defined as an edge where the first PDL side wall of the pixel defining layer 140 adjoins an upper surface of the pixel electrode PE, may form a closed shape in a plan view. A second edge of the pixel defining layer 140, defined as an edge where the second PDL side wall of the pixel defining layer 140 adjoins the upper surface of the pixel electrode PE, may form a closed shape in a plan view. For example, each of the first edge and the second edge of the pixel defining layer 140 may have a quadrangular shape in a plan view, but this is an example, and embodiments are not limited thereto. For example, each of the first edge and the second edge of the pixel defining layer 140 may have various shapes with or without curves, such as a circle, an oval, an octagon, or the like in a plan view. That is, each of the first pixel opening 140OP1 and the second pixel opening 140OP2 may have various shapes, such as a quadrangular shape, a circular shape, an oval shape, or an octagonal shape in a plan view.

In a plan view, an area inside the first edge of the pixel defining layer 140 may be defined as a first-first area A11 (shown in FIG. 6), and an area inside the second edge of the pixel defining layer 140 may be defined as a second-first area A21 (shown in FIG. 6). A size of the first-first area A11 may be equal to a size of the second-first area A21.

An emission layer EL may be disposed on the pixel electrode PE. In some embodiments, the emission layer EL may include at least one of an organic light emitting material or quantum dot.

In an embodiment, the organic light emitting material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination.

In an embodiment, the quantum dot may include a core including a Group II-VI compound, a Group III-V compound, a Group IV-VI compound, a Group IV element, and/or a Group IV compound. In an embodiment, the quantum dot may have a core-shell structure including the core and a shell surrounding the core. The shell may serve as a protection layer for preventing the core from being chemically denatured to maintain semiconductor characteristics, and may serve as a charging layer for imparting electrophoretic characteristics to the quantum dot.

The emission layer EL may overlap the first pixel opening 140OP1 and the second pixel opening 140OP2 of the pixel defining layer 140. A portion of the emission layer EL may be disposed within the first pixel opening 140OP1, and another portion of the emission layer EL may be disposed within the second pixel opening 140OP2. That is, the portion of the emission layer EL may overlap the first portion PE1 of the pixel electrode PE, and the another portion of the emission layer EL may overlap the second portion PE2 of the pixel electrode PE. Light may be emitted only from portions of the emission layer EL overlapping the first-first area A11 and the second-first area A21.

In an embodiment, as illustrated in FIG. 6, the emission layer EL may overlap the third portion PE3 of the pixel electrode PE. Light may not be emitted from a portion of the emission layer EL overlapping the third portion PE3 of the pixel electrode PE. For example, the emission layer EL may be on the pixel defining layer 140 to overlap the entire upper surface of the corresponding pixel electrode PE without overlapping a pixel electrode of an adjacent pixel. Specifically, the emission layer EL may be continuously disposed on a portion of an upper surface of the pixel defining layer 140 above exactly one pixel electrode PE, the first PDL side wall of the pixel defining layer 140, the second PDL side wall of the pixel defining layer 140, the first portion PE1 of the pixel electrode PE exposed by the first pixel opening 140OP1, and the second portion PE2 of the pixel electrode PE exposed by the second pixel opening 140OP2. In another embodiment, the emission layer EL may be disposed only on the first portion PE1 of the pixel electrode PE at the base of the first pixel opening 140OP1 and the second portion PE2 of the pixel electrode PE at the base of the second pixel opening 140OP2.

A common electrode CE may be disposed on the emission layer EL. The common electrode CE may also be disposed on the pixel defining layer 140. The common electrode CE may include a conductive material. The pixel electrode PE, the emission layer EL, and the common electrode CE may constitute the light emitting element LED. The light emitting element LED may further include various functional layers (e.g., a hole injection layer, a hole transport layer, an electron transport layer, an electron injection layer, or the like) disposed between the pixel electrode PE and the emission layer EL or between the emission layer EL and the common electrode CE.

The encapsulation layer may be disposed on the common electrode CE. The encapsulation layer may cover the light emitting element LED. The encapsulation layer may include at least one inorganic encapsulation layer and at least one organic encapsulation layer. In an embodiment, the encapsulation layer may include a first inorganic encapsulation layer 151 disposed on the common electrode CE, an organic encapsulation layer 152 disposed on the first inorganic encapsulation layer 151, and a second inorganic encapsulation layer 153 disposed on the organic encapsulation layer 152.

The touch sensing layer may be disposed on the second inorganic encapsulation layer 153. In an embodiment, the touch sensing layer may include a first touch electrode layer 162, a first touch insulating layer 164, a second touch electrode layer 172, and a second touch insulating layer 174.

The first touch electrode layer 162 may be disposed on the second inorganic encapsulation layer 153. In an embodiment, an insulating layer may be disposed between the first touch electrode layer 162 and the second inorganic encapsulation layer 153. The first touch electrode layer 162 may include a conductive material.

The first touch insulating layer 164 may be disposed on the first touch electrode layer 162. The first touch insulating layer 164 may cover the first touch electrode layer 162 on the second inorganic encapsulation layer 153. The first touch insulating layer 164 may include an inorganic insulating material.

The second touch electrode layer 172 may be disposed on the first touch insulating layer 164. The second touch electrode layer 172 may include a conductive material.

The second touch insulating layer 174 may be disposed on the second touch electrode layer 172. The second touch insulating layer 174 may cover the second touch electrode layer 172, which is on the first touch insulating layer 164. The second touch insulating layer 174 may include an inorganic insulating material.

The first touch electrode layer 162 and the second touch electrode layer 172 may constitute a touch electrode. The touch electrode may have a mesh structure in plan view. In an embodiment, the touch electrode having a mesh structure may not be positioned above the first pixel opening 140OP1 and the second pixel opening 140OP2 of the pixel defining layer 140. For example, the touch electrode may have a mesh structure that defines touch openings respectively corresponding to the pixel electrodes, each of the touch openings being above the entirety of the corresponding pixel electrode PE and having a greater size than the corresponding pixel electrode PE. For example, in a plan view, the touch electrode may be disposed between adjacent pixel electrodes PE, but may not be disposed between the first pixel opening 140OP1 and the second pixel opening 140OP2.

The first refractive layer 180 may be disposed on the second touch insulating layer 174. The first refractive layer 180 may include an organic insulating material, and may have a first refractive index. For example, the first refractive index may be in a range of about 1.4 to about 1.6, but embodiments are not limited thereto.

The first refractive layer 180 may define a first opening 180OP1 above the first pixel opening 140OP1 and a second opening 180OP2 above the second pixel opening 140OP2. As illustrated in FIG. 3, in a plan view, the first opening 180OP1 and the second opening 180OP2 may be spaced apart from each other.

The first refractive layer 180 may have a lower surface 181, an upper surface 182, a first refractive side wall 183a, and a second refractive side wall 183b. The lower surface 181 of the first refractive layer 180 may face the pixel defining layer 140. The upper surface 182 of the first refractive layer 180 may be opposite to the lower surface 181, and may face the second refractive layer 190. The first refractive side wall 183a of the first refractive layer 180 may define the first opening 180OP1. The second refractive side wall 183b of the first refractive layer 180 may define the second opening 180OP2.

The second refractive layer 190 may be disposed on the first refractive layer 180. The second refractive layer 190 may have a substantially flat upper surface. The second refractive layer 190 may fill the first opening 180OP1 and the second opening 180OP2 of the first refractive layer 180. For example, the second refractive layer 190 may contact the upper surface 182, the first refractive side wall 183a, and the second refractive side wall 183b of the first refractive layer 180. The second refractive layer 190 may include an organic insulating material, and may have a second refractive index greater than the first refractive index. For example, the second refractive index may be in a range of about 1.6 to about 1.8, but embodiments are not limited thereto.

In an embodiment, in a plan view, a size of the first opening 180OP1 of the first refractive layer 180 may be greater than a size of the first pixel opening 140OP1 of the pixel defining layer 140. As illustrated in FIG. 3, a first lower edge 184a of the first refractive layer 180, defined as an edge where the first refractive side wall 183a adjoins the lower surface 181, may form a closed shape in a plan view. For example, in a plan view, the first lower edge 184a of the first refractive layer 180 may be outside of an area enclosed by the first edge of the pixel defining layer 140 and may surround the first edge of the pixel defining layer 140. That is, in a plan view, the first lower edge 184a of the first refractive layer 180 may be distanced from the outer edge of the first pixel opening 140OP1 and may surround the first pixel opening 140OP1. As a result, the base of the first opening 180OP1 is wider than the base of the first pixel opening 140OP1. For example, in a plan view, a distance between the first lower edge 184a of the first refractive layer 180 and the first edge of the pixel defining layer 140 may be substantially constant.

In an embodiment, in a plan view, a size of the second opening 180OP2 of the first refractive layer 180 may be greater than a size of the second pixel opening 140OP2 of the pixel defining layer 140. A second lower edge 184b of the first refractive layer 180, defined as an edge where the second refractive side wall 183b adjoins the lower surface 181, may form a closed shape in a plan view. For example, in a plan view, the second lower edge 184b of the first refractive layer 180 may be outside of an area enclosed by the second edge of the pixel defining layer 140 and may surround the second edge of the pixel defining layer 140. That is, in a plan view, the second lower edge 184b of the first refractive layer 180 may be distanced from the outer edge of the second pixel opening 140OP2 and may surround the second pixel opening 140OP2. The base of the second opening 180OP2 is wider than the base of the second pixel opening 140OP2. For example, in a plan view, a distance between the second lower edge 184b of the first refractive layer 180 and the second edge of the pixel defining layer 140 may be substantially constant.

For example, in a plan view, the distance between the first lower edge 184a of the first refractive layer 180 and the first edge of the pixel defining layer 140 may be equal to the distance between the second lower edge 184b of the first refractive layer 180 and the second edge of the pixel defining layer 140.

Each of the first refractive side wall 183a and the second refractive side wall 183b of the first refractive layer 180 may be inclined at a predetermined angle from the lower surface 181. As described above, the first refractive side wall 183a and the second refractive side wall 183b of the first refractive layer 180 may adjoin the second refractive layer 190 having a greater refractive index than the first refractive layer 180. Accordingly, a portion of the light emitted from the emission layer EL may be totally reflected at an interface between the first refractive side wall 183a of the first refractive layer 180 and the second refractive layer 190. Additionally, a portion of the light emitted from the emission layer EL may be totally reflected at an interface between the second refractive side wall 183b of the first refractive layer 180 and the second refractive layer 190. Accordingly, the light emitted from the light emitting element LED may be directed to an area in front of the display device 10, and a front luminance of the display device 10 may be improved.

In an embodiment, an angle θ1 between the first refractive side wall 183a and the lower surface 181 of the first refractive layer 180 may be in a range of about 30 degrees to about 70 degrees. If the angle θ1 between the first refractive side wall 183a and the lower surface 181 of the first refractive layer 180 is less than 30 degrees, light emitted from the emission layer EL may not enter the interface between the first refractive side wall 183a of the first refractive layer 180 and the second refractive layer 190, and thus, the light emitted from the emission layer EL may not be completely reflected. If the angle θ1 between the first refractive side wall 183a and the lower surface 181 of the first refractive layer 180 is larger than 70 degrees, the light that is reflected at the interface between the first refractive side wall 183a and the lower surface 181 of the first refractive layer 180 may not be emitted to the front side of the display device 10. In some embodiments, the angle θ1 between the first refractive side wall 183a and the lower surface 181 of the first refractive layer 180 may be in a range of about 40 degrees to about 50 degrees.

In an embodiment, an angle θ2 between the second refractive side wall 183b and the lower surface 181 of the first refractive layer 180 may be in a range of about 30 degrees to about 70 degrees. For example, the angle θ2 between the second refractive side wall 183b and the lower surface 181 of the first refractive layer 180 may be in a range of about 40 degrees to about 50 degrees. For example, the angle θ1 between the first refractive side wall 183a and the lower surface 181 may be equal to the angle θ2 between the second refractive side wall 183b and the lower surface 181.

As illustrated in FIG. 3, a first upper edge 185a of the first refractive layer 180, defined as an edge where the first refractive side wall 183a adjoins the upper surface 182, may form a closed shape in a plan view. For example, in a plan view, the first upper edge 185a of the first refractive layer 180 may be positioned outside of the edge of the first lower edge 184a and may surround the first lower edge 184a. For example, in a plan view, a distance between the first upper edge 185a and the first lower edge 184a of the first refractive layer 180 may be substantially constant. In a plan view, the first upper edge 185a of the first refractive layer 180 may be positioned outside of the first pixel opening 140OP1 and may surround the first pixel opening 140OP1.

A second upper edge 185b of the first refractive layer 180, defined as an edge where the second refractive side wall 183b adjoins the upper surface 182, may form a closed shape in a plan view. For example, in a plan view, the second upper edge 185b of the first refractive layer 180 may be outside of the edge of the second lower edge 184b and may surround the second lower edge 184b. For example, in a plan view, a distance between the second upper edge 185b and the second lower edge 184b of the first refractive layer 180 may be substantially constant. In a plan view, the second upper edge 185b of the first refractive layer 180 may be outside of the second pixel opening 140OP2 and may surround the second pixel opening 140OP2.

For example, in a plan view, the distance between the first upper edge 185a and the first lower edge 184a of the first refractive layer 180 may be equal to the distance between the second upper edge 185b and the second lower edge 184b of the first refractive layer 180.

In an embodiment, as illustrated in FIG. 6, between the first opening 180OP1 and the second opening 180OP2, the first refractive layer 180 may have a tapered trapezoidal cross-sectional shape in which a length of a lower side is longer than a length of an upper side. That is, the first upper edge 185a and the second upper edge 185b of the first refractive layer 180a may not adjoin each other.

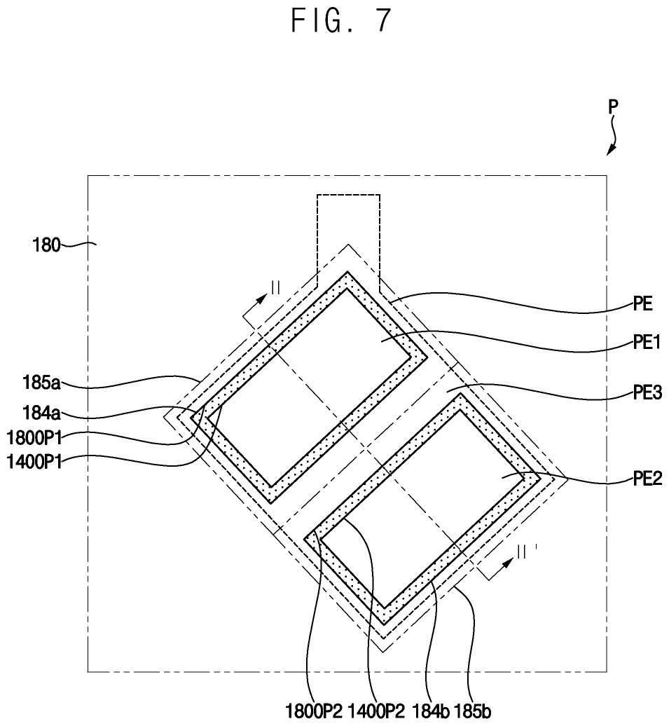

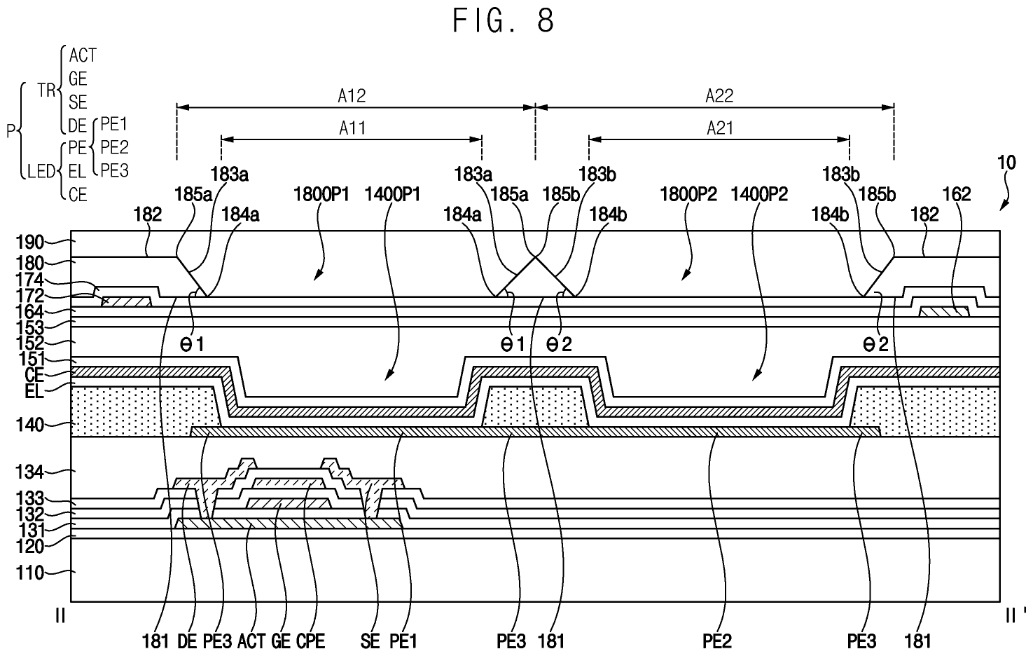

FIG. 7 is a plan view illustrating a pixel according to an embodiment. FIG. 8 is a cross-sectional view taken along a line II-II′ of FIG. 7.

Referring to FIGS. 7 and 8, in an embodiment, between the first opening 180OP1 and the second opening 180OP2, the first refractive layer 180 may have a triangular cross-sectional shape. That is, the first upper edge 185a and the second upper edge 185b of the first refractive layer 180a may adjoin each other.

Referring again to FIGS. 3 to 6, in a plan view, an area enclosed by the first upper edge 185a of the first refractive layer 180 may be defined as a first-second area A12, and an inner area enclosed by the second upper edge 185b may be defined as a second-second area A22. A size of the first-second area A12 may be greater than the size of the first-first area A11, and a size of the second-second area A22 may be greater than the size of the second-first area A21. In some embodiments, the size of the first-second area A12 may be equal to the size of the second-second area A22.

As described above, light may be emitted only from portions of the emission layer EL overlapping the first-first area A11 and the second-first area A21, but a portion of the light emitted from the emission layer EL may be totally reflected at the interface between the first refractive side wall 183a of the first refractive layer 180 and the second refractive layer 190 or the interface between the second refractive side wall 183b of the first refractive layer 180 and the second refractive layer 190. Accordingly, light may be emitted from the entire the first-second area A12 and the second-second area A22 of the display device 10, the front luminance of the display device 10 may be improved, and a display quality of the display device 10 may be improved.

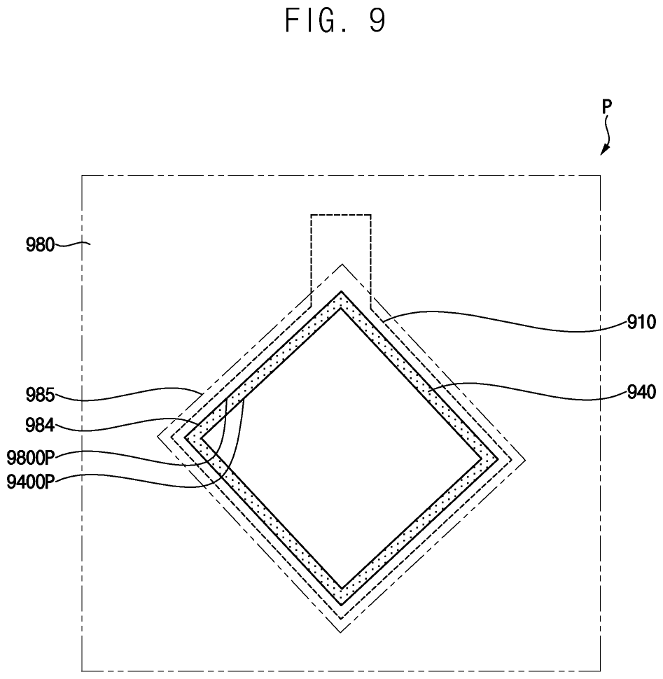

In addition, according to the display device 10 according to embodiments, two first and second pixel openings 140OP1 and 140OP2 may be defined corresponding to one pixel electrode PE, and the first and second openings 180OP1 and 180OP2 of the first refractive layer 180 may be defined respectively corresponding to the first and second pixel openings 140OP1 and 140OP2. Accordingly, compared to a comparative example (e.g., FIG. 9) in which one pixel opening is defined corresponding to one pixel electrode PE, an area where the refractive side walls 183a and 183b of the first refractive layer 180 are disposed (i.e., an area that totally reflects a portion of the light emitted from the emission layer EL) may be greater. Accordingly, the front luminance of the display device 10 may be further improved.

Hereinafter, effects of the display device 10 according to embodiments of FIGS. 3 to 6 will be described in more detail using a specific example.

FIG. 9 is a plan view illustrating a pixel according to a comparative example.

FIG. 9 may correspond to FIG. 3. Referring to the comparative example shown in FIG. 9, a pixel defining layer 940 may define one pixel opening 940OP corresponding to one pixel electrode 910, and a first refractive layer 980 may define one opening 980OP larger than the pixel opening 940OP. It is assumed that a planar shape of the pixel opening 940OP is a square having each side of 14 micrometers, and it is assumed that a distance between an upper edge 985 of the first refractive layer 980 and the pixel opening 940OP is constant at 2 micrometers. In this case, a first size of the pixel opening 940OP is 196 micrometer², and a second size of an inner area of the upper edge 985 of the first refractive layer is 324 micrometer².

For comparison to the comparative example of FIG. 9, in the embodiments of FIGS. 3 to 6, it is assumed that a planar shape of each of the first pixel opening 140OP1 and the second pixel opening 140OP2 is rectangular with a long side of 14 micrometer and a short side of 7 micrometer, and it is assumed that each of a distance between the first upper edge 185a of the first refractive layer 180 and the first pixel opening 140OP1 and a distance between the second upper edge 185b of the first refractive layer 180 and the second pixel opening 140OP2 is constant at 2 micrometer. In this case, the size of the first pixel opening 140OP1 (the size of the first-first area A11) is 98 micrometer², and a size of the inner area of the first upper edge 185a of the first refractive layer 180 (the size of the first-second area A12) is 198 micrometer². Likewise, the size of the second pixel opening 140OP2 (the size of the second-first area A21) is 98 micrometer², and a size of the inner area of the second upper edge 185b of the first refractive layer 180 (the size of the second-second area A22) is 198 micrometer². That is, a third size, which is the sum of the size of the first-first area A11 and the size of the second-first area A21, is 196 micrometer², which is equal to the first size in the comparative example of FIG. 9. However, a fourth size, which is the sum of the size of the first-second area A12 and the size of the second-second area A22, is 396 micrometer², which is greater than the second size in the comparative example of FIG. 9.

Referring to this, even if the size of the area where light is emitted from the emission layer EL are the same (the third size is the same as the first size), the size of the entire area where light is emitted from the front of the display device is larger in the embodiments of FIGS. 3 to 6 than in the comparative example of FIG. 9 (the fourth size is larger than the second size). This is because the area where the refractive side walls 183a and 183b of the first refractive layer 180 that reflect a portion of the light emitted from the emission layer EL is greater in the embodiments of FIGS. 3 to 6 than in the comparative example of FIG. 9. Accordingly, the front luminance of the display device 10 may be further improved.

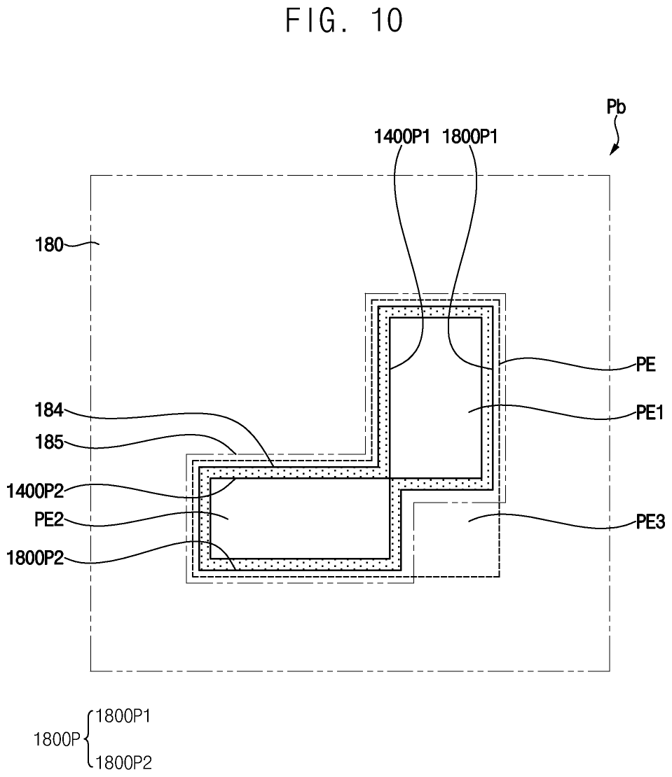

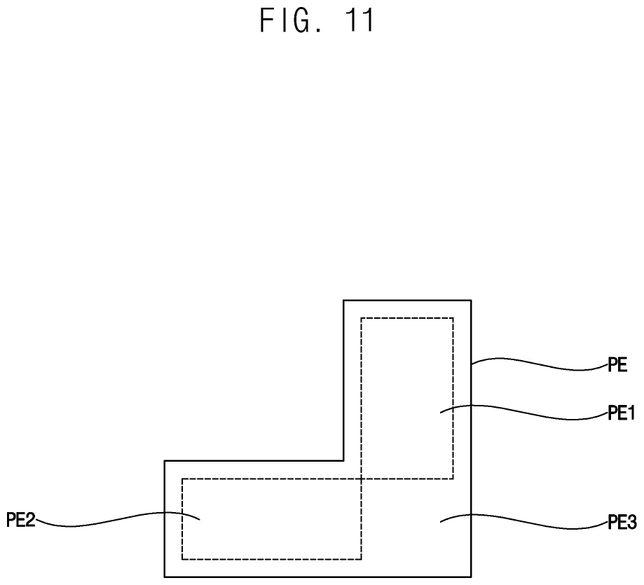

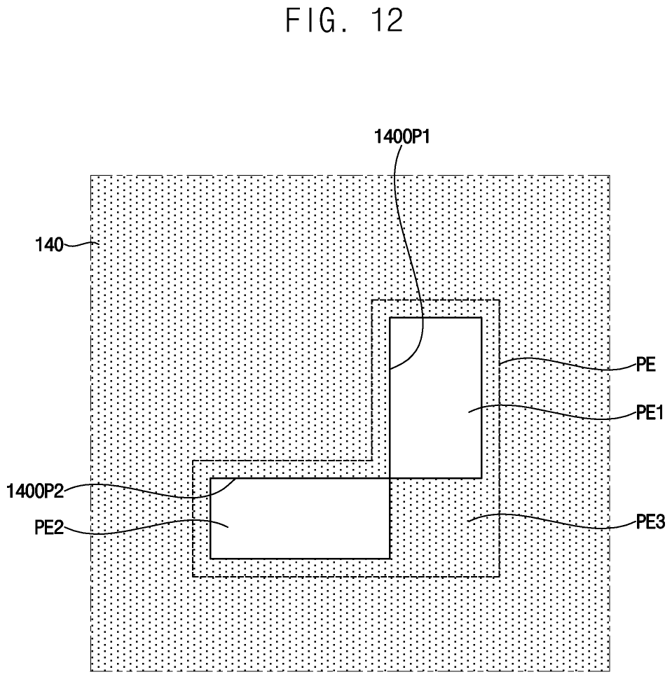

FIGS. 10 to 12 are plan views illustrating a pixel according to an embodiment.

Hereinafter, a pixel Pb of FIGS. 10 to 12 will be described focusing on differences from the pixel P described with reference to FIGS. 3 to 6, and redundant descriptions may be omitted or abbreviated.

Referring to FIGS. 10 to 12, a pixel electrode PE may include a first portion PE1, a second portion PE2, and a third portion PE3. In a plan view, the first portion PEL and the second portion PE2 may adjoin each other. For example, as illustrated in FIG. 10, a vertex of the first portion PE1 may adjoin a vertex of the second portion PE2 in a plan view. The third portion PE3 may surround each of the first portion PEL and the second portion PE2 in a plan view. The first to third portions PE1, PE2, and PE3 of the pixel electrode PE may be integrally provided.

A pixel defining layer 140 may define a first pixel opening 140OP1 exposing the first portion PE1 of the pixel electrode PE and a second pixel opening 140OP2 exposing the second portion PE2 of the pixel electrode PE. In a plan view, the first pixel opening 140OP1 and the second pixel opening 140OP2 may adjoin each other. The pixel defining layer 140 may cover the third portion PE3 of the pixel electrode PE.

A first refractive layer 180 may define a first opening 180OP1 above the first pixel opening 140OP1 and a second opening 180OP2 above the second pixel opening 140OP2. As illustrated in FIG. 10, in a plan view, the first opening 180OP1 and the second opening 180OP2 may be connected to each other to form an opening 180OP. That is, the first opening 180OP1 and the second opening 180OP2 of the first refractive layer 180 may be integrally provided.

A refractive side wall of the first refractive layer 180 may define the opening 180OP. In an embodiment, in a plan view, a size of the opening 180OP of the first refractive layer 180 may be greater than the sum of a size of the first pixel opening 140OP1 of the pixel defining layer 140 and a size of the second pixel opening 140OP2 of the pixel defining layer 140. As illustrated in FIG. 10, a lower edge 184 of the first refractive layer 180, defined as an edge where the refractive side wall of the first refractive layer 180 adjoins a lower surface of the first refractive layer 180, may form a closed shape in a plan view. For example, in a plan view, the lower edge 184 of the first refractive layer 180 may be outside of the first pixel opening 140OP1 and the second pixel opening 140OP2 of the pixel defining layer 140 and may surround the entire the first pixel opening 140OP1 and the second pixel opening 140OP2.

An upper edge 185 of the first refractive layer 180, defined as an edge where the refractive side wall of the first refractive layer 180 adjoins an upper surface of the first refractive layer 180, may form a closed shape in a plan view. For example, in a plan view, the upper edge 185 of the first refractive layer 180 may be outside of the lower edge 184 and may surround the lower edge 184. For example, in a plan view, a distance between the lower edge 184 and the upper edge 185 of the first refractive layer 180 may be substantially constant. For example, in a plan view, the upper edge 185 of the first refractive layer 180 may be outside of the first pixel opening 140OP1 and the second pixel opening 140OP2 of the pixel defining layer 140 and may surround the entire the first pixel opening 140OP1 and the second pixel opening 140OP2.

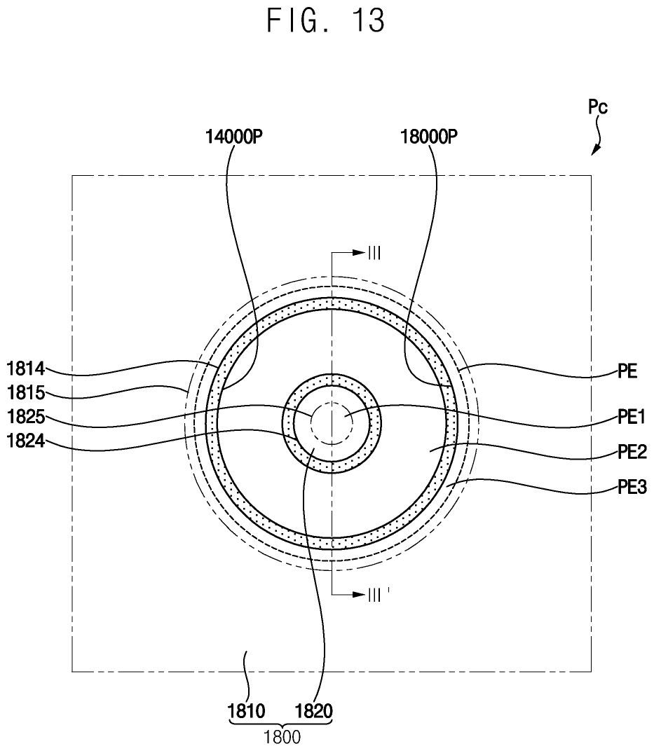

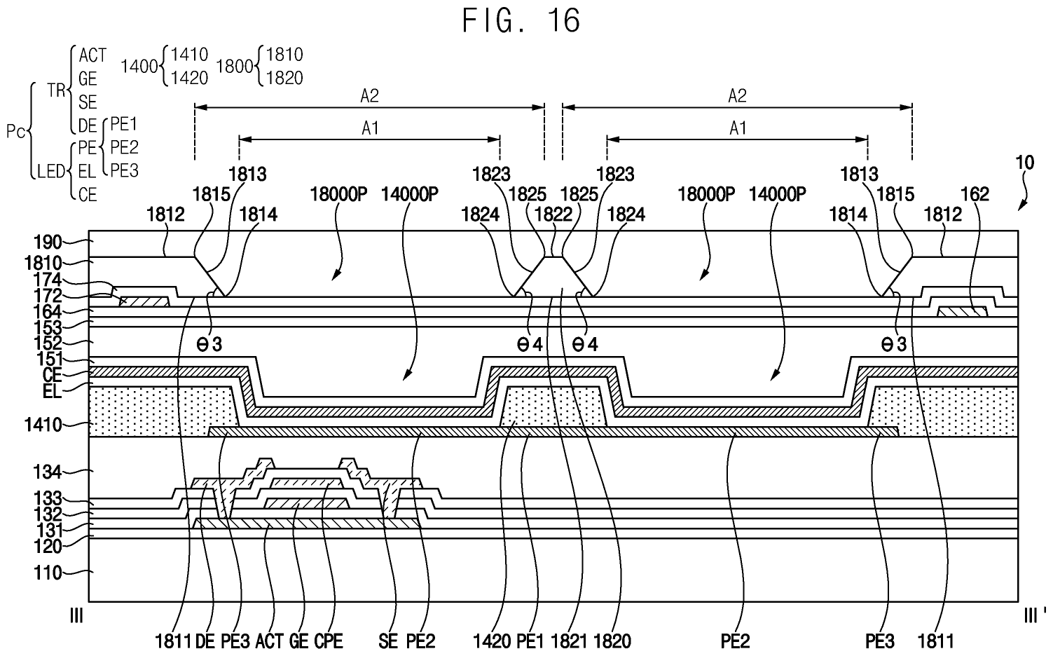

FIGS. 13 to 15 are plan views illustrating a pixel according to an embodiment. FIG. 16 is a cross-sectional view taken along a line III-III′ of FIG. 13.

Hereinafter, a pixel Pc of FIGS. 13 to 16 will be described focusing on differences from the pixel P described with reference to FIGS. 3 to 6, and repeated descriptions may be omitted or simplified.

Referring to FIGS. 13 to 16, a pixel electrode PE may include a first portion PE1, a second portion PE2, and a third portion PE3. In a plan view, the second portion PE2 may be positioned outside the first portion PE1, and the third portion PE3 may be positioned outside the second portion PE2. For example, in a plan view, the second portion PE2 may surround the first portion PE1, and the third portion PE3 may surround the second portion PE2. That is, each of the second portion PE2 and the third portion PE3 of the pixel electrode PE may have a ring shape in a plan view. The first to third portions PE1, PE2, and PE3 of the pixel electrode PE may be integrally provided.

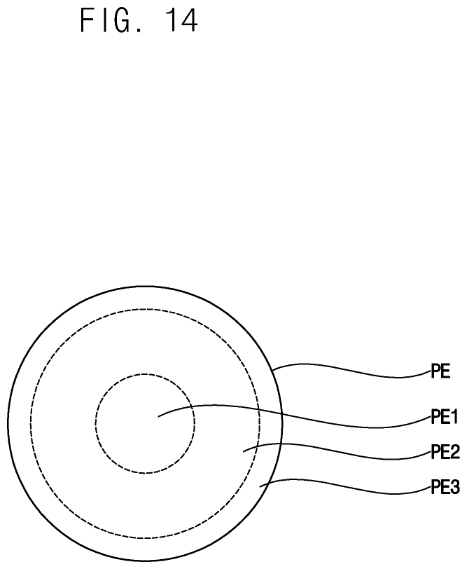

FIG. 14 illustrates that the first portion PE1 of the pixel electrode PE has a circular shape in a plan view, and each of the second portion PE2 and the third portion PE3 has a circular shape in a plan view wherein the first, second, and third portions PE1, PE2, PE3 are arranged concentrically. However, this is an example, and embodiments are not limited to the arrangement that is explicitly depicted. For example, in a plan view, the first portion PE1 of the pixel electrode PE may have various shapes such as an oval, a square, an octagon, or the like. Similarly, each of the second portion PE2 and the third portion PE3 may have various shapes such as oval, square, octagon, or the like.

A pixel defining layer 1400 may define a pixel opening 1400OP exposing the second portion PE2 of the pixel electrode PE. For example, the pixel opening 1400OP may have a ring shape in a plan view. For example, the pixel opening 1400OP may have a circular shape in a plan view.

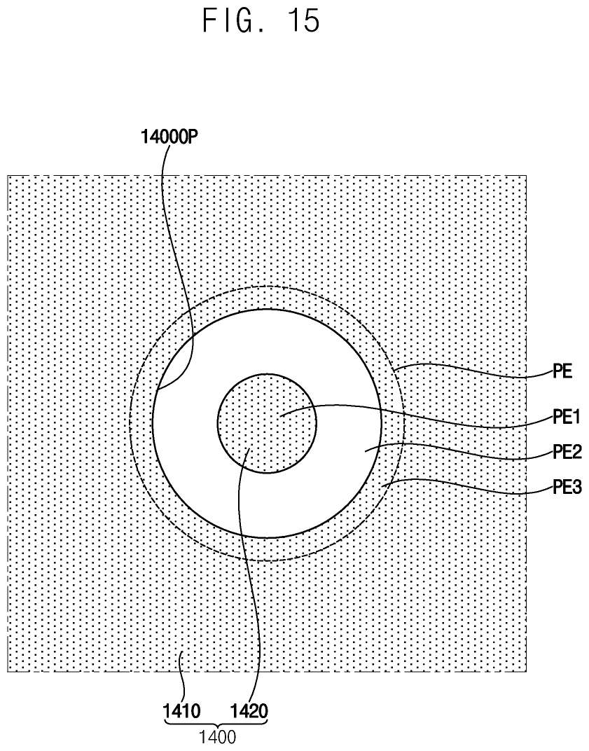

As illustrated in FIG. 15, the pixel defining layer 1400 may include a first mesh portion 1410 and a first island portion 1420. The first mesh portion 1410 may be positioned outside the second portion PE2 of the pixel electrode PE. The first mesh portion 1410 may cover the third portion PE3 of the pixel electrode PE. A mesh side wall of the first mesh portion 1410 may face the first island portion 1420. A first edge of the first mesh portion 1410, defined as an edge where the mesh side wall of the first mesh portion 1410 adjoins an upper surface of the pixel electrode PE, may form a closed shape in a plan view.

The first island portion 1420 may be disposed to overlap the first portion PE1 of each pixel electrode PE, and may have the same shape as the first portion PE1. The first island portion 1420 may be spaced apart from the first mesh portion 1410, and may overlap the first portion PE1 of the pixel electrode PE. An island side wall of the first island portion 1420 may face the first mesh portion 1410. A second edge of the first island portion 1420, defined as an edge where the mesh side wall of the first island portion 1420 adjoins the upper surface of the pixel electrode PE, may form a closed shape in a plan view.

The pixel opening 1400OP may be defined by the mesh side wall of the first mesh portion 1410 and the island side wall of the first island portion 1420. In a plan view, a ring-shaped area inside the first edge and outside the second edge of the pixel defining layer 1400 may be defined as a first area A1. For example, the first area A1 may have a circular shape in a plan view. Light may be emitted only from a portion of the emission layer EL that overlaps the first area A1.

The first refractive layer 1800 may define an opening 1800OP overlapping the pixel opening 1400OP. The first refractive layer 1800 may include a second mesh portion 1810 and a second island portion 1820. The second mesh portion 1810 may be positioned outside the second portion PE2 of the pixel electrode PE. The second mesh portion 1810 may overlap a portion of the third portion PE3 of the pixel electrode PE.

The second island portion 1820 may be disposed to correspond to the first portion PE1 of each pixel electrode PE. The second island portion 1820 may be disposed to correspond to the first island portion 1420. The second island portion 1820 may be spaced apart from the second mesh portion 1810, and may overlap the first portion PE1 of the pixel electrode PE and the first island portion 1420 of the pixel defining layer 1400.

In one embodiment, as illustrated in FIG. 16, the second island portion 1820 may have a tapered trapezoidal cross-sectional shape in which a length of a lower side is longer than a length of an upper side. In another embodiment, the second island portion 1820 may have a triangular cross-sectional shape.

A mesh side wall 1813 of the second mesh portion 1810 may face the second island portion 1820. An island side wall 1823 of the second island portion 1820 may face the second mesh portion 1810. The opening 1800OP may be defined by the mesh side wall 1813 of the second mesh portion 1810 and the island side wall 1823 of the second island portion 1820.

In an embodiment, in a plan view, a size of the opening 1800OP of the first refractive layer 1800 may be greater than a size of the pixel opening 1400OP of the pixel defining layer 1400.

As illustrated in FIG. 13, a first lower edge 1814 of the second mesh portion 1810, defined as an edge where the mesh side wall 1813 adjoins a lower surface 1811, may form a closed shape in a plan view. For example, in a plan view, the first lower edge 1814 of the second mesh portion 1810 may be outside of the first edge of the first mesh portion 1410 and may surround the first edge of the first mesh portion 1410. That is, in a plan view, the first lower edge 1814 of the second mesh portion 1810 may be outside of the pixel opening 1400OP and may surround the pixel opening 1400OP. For example, in a plan view, a distance between the first lower edge 1814 of the second mesh portion 1810 and the first edge of the first mesh portion 1410 may be substantially constant.

A second lower edge 1824 of the second island portion 1820, defined as an edge where the island side wall 1823 adjoins a lower surface 1821, may form a closed shape in a plan view. For example, in a plan view, the second lower edge 1824 of the second island portion 1820 may be outside of the second edge of the first island portion 1420. For example, in a plan view, a distance between the second lower edge 1824 of the second island portion 1820 and the second edge of the first island portion 1420 may be substantially constant.

For example, in a plan view, the distance between the first lower edge 1814 of the second mesh portion 1810 and the first edge of the first mesh portion 1410 may be equal to the distance between the second lower edge 1824 of the second island portion 1820 and the second edge of the first island portion 1420.

The mesh side wall 1813 of the second mesh portion 1810 may be inclined at a predetermined angle with respect to the lower surface 1811. In an embodiment, an angle θ3 between the mesh side wall 1813 and the lower surface 1811 of the second mesh portion 1810 may be in a range of about 30 degrees to about 70 degrees. For example, the angle θ3 between the mesh side wall 1813 and the lower surface 1811 of the second mesh portion 1810 may be in a range of about 40 degrees to about 50 degrees.

The island side wall 1823 of the second island portion 1820 may be inclined at a predetermined angle with respect to the lower surface 1821. In an embodiment, an angle θ4 between the island side wall 1823 and the lower surface 1821 of the second island portion 1820 may be in a range of about 30 degrees to about 70 degrees. For example, the angle θ4 between the island side wall 1823 and the lower surface 1821 of the second island portion 1820 may be in a range of about 40 degrees to about 50 degrees. For example, the angle θ3 between the mesh side wall 1813 and the lower surface 1811 of the second mesh portion 1810 may be equal to the angle θ4 between the island side wall 1823 and the lower surface 1821 of the second island portion 1820.

As illustrated in FIG. 13, a first upper edge 1815 of the second mesh portion 1810, defined as an edge where the mesh side wall 1813 adjoins an upper surface 1812, may form a closed shape in a plan view. For example, in a plan view, the first upper edge 1815 of the second mesh portion 1810 may be outside of the first lower edge 1814 and may surround the first lower edge 1814. For example, in a plan view, a distance between the first upper edge 1815 and the first lower edge 1814 of the second mesh portion 1810 may be substantially constant. In a plan view, the first upper edge 1815 of the second mesh portion 1810 may be outside of the pixel opening 1400OP and may surround the pixel opening 1400OP.

A second upper edge 1825 of the second island portion 1820, defined as an edge where the island side wall 1823 adjoins an upper surface 1822, may form a closed shape in a plan view. For example, in a plan view, the second upper edge 1825 of the second island portion 1820 may be spaced from and be outside of the second lower edge 1824. For example, in a plan view, a distance between the second upper edge 1825 and the second lower edge 1824 of the second island portion 1820 may be substantially constant.

In a plan view, the distance between the first upper edge 1815 and the first lower edge 1814 of the second mesh portion 1810 may be equal to the distance between the second upper edge 1825 and the second lower edge 1824 of the second island portion 1820.

In a plan view, an area between the first upper edge 1815 of the second mesh portion 1810 and the second upper edge 1825 of the second island portion 1820 may be defined as a second area A2. For example, the second area A2 may have a hollow circular shape in a plan view. A size of the second area A2 may be greater than a size of the first area A1.

As described above, light may be emitted only from a portion of the emission layer EL in the first area A1. A portion of the light emitted from the emission layer EL may be totally reflected at an interface between the mesh side wall 1813 of the second mesh portion 1810 and the second refractive layer 190 or an interface between the outer side surface 1823 of the second island portion 1820 and the second refractive layer 190. Accordingly, light may be emitted from the entire the second area A2 of the display device 10, improving the front luminance of the display device 10. The improved front luminance in turn improves the display quality of the display device 10.

Although embodiments and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a thin film transistor;
a pixel electrode electrically connected to the thin film transistor and including a first portion, a second portion, and a third portion, the third portion being positioned outside the first portion and the second portion;
a pixel defining layer disposed on the pixel electrode and defining a first pixel opening above the first portion of the pixel electrode and a second pixel opening above the second portion of the pixel electrode;
an emission layer disposed on the pixel electrode and overlapping the first pixel opening and the second pixel opening;
a first refractive layer disposed on the pixel defining layer and defining a first opening above the first pixel opening and a second opening above the second pixel opening; and
a second refractive layer disposed on the first refractive layer, filling the first opening and the second opening of the first refractive layer, and having a refractive index greater than a refractive index of the first refractive layer.

2. The display device of claim 1, wherein the first portion, the second portion, and the third portion of the pixel electrode are integrated.

3. The display device of claim 2, wherein
the first portion of the pixel electrode and the second portion of the pixel electrode are spaced apart from each other, and
a portion of the third portion of the pixel electrode is positioned between the first portion of the pixel electrode and the second portion of the pixel electrode.

4. The display device of claim 3, wherein
the first pixel opening and the second pixel opening are spaced apart from each other, and
the first opening and the second opening are spaced apart from each other.

5. The display device of claim 4, wherein the first refractive layer between the first opening and the second opening has a trapezoidal cross-sectional shape.

6. The display device of claim 4, wherein the first opening and the second opening have sidewalls that are inclined with respect to a lower surface of the first refractive layer.

7. The display device of claim 4, wherein
the first refractive layer has a lower surface facing the pixel defining layer, an upper surface opposite to the lower surface, a first refractive side wall defining the first opening, and a second refractive side wall defining the second opening,
a first upper edge of the first refractive layer, defined as an edge where the upper surface of the first refractive layer adjoins the first refractive side wall of the first opening, surrounds the first pixel opening in a plan view, and
a second upper edge of the first refractive layer, defined as an edge where the upper surface of the first refractive layer adjoins the second refractive side wall of the second opening, surrounds the second pixel opening in a plan view.

8. The display device of claim 7, wherein an angle between the lower surface of the first refractive layer and the first refractive side wall of the first opening is in a range of about 30 degrees to about 70 degrees.

9. The display device of claim 3, wherein the emission layer overlaps all of the first portion of the pixel electrode, the second portion of the pixel electrode, and the third portion of the pixel electrode.

10. The display device of claim 2, wherein the first portion of the pixel electrode and the second portion of the pixel electrode adjoin each other.

11. The display device of claim 10, wherein
the first pixel opening and the second pixel opening adjoin with each other, and
the first opening and the second opening are integrated.

12. The display device of claim 1, wherein
the first refractive layer has a lower surface facing the pixel defining layer, an upper surface opposite to the lower surface, and a side wall defining the first opening and the second opening, and
an upper edge of the first refractive layer, defined as an edge where the upper surface of the first refractive layer adjoins the side wall of the first refractive layer, surrounds the first pixel opening and the second pixel opening in a plan view.

13. The display device of claim 1, wherein in a plan view,
a size of the first opening is greater than a size of the first pixel opening, and
a size of the second opening is greater than a size of the second pixel opening.

14. The display device of claim 11, further comprising:
an encapsulation layer disposed on the pixel defining layer and the emission layer; and
a touch electrode layer disposed between the encapsulation layer and the first refractive layer.

15. A display device comprising:
a thin film transistor;
a pixel electrode electrically connected to the thin film transistor and including a first portion, a second portion positioned outside the first portion, and a third portion positioned outside the second portion;
a pixel defining layer disposed on the pixel electrode and defining a pixel opening above the second portion of the pixel electrode, the pixel opening having a ring shape in a plan view;
an emission layer disposed on the pixel electrode and overlapping the pixel opening;
a first refractive layer disposed on the pixel defining layer and defining an opening above the pixel opening, the opening having a ring shape in a plan view; and
a second refractive layer disposed on the first refractive layer, filling the opening of the first refractive layer, and having a refractive index greater than a refractive index of the first refractive layer.

16. The display device of claim 15, wherein the first refractive layer includes:
a mesh portion positioned outside the second portion of the pixel electrode in a plan view; and
an island portion spaced apart from the mesh portion and positioned on the first portion of the pixel electrode in a plan view.

17. The display device of claim 16, wherein the island portion of the first refractive layer has a trapezoidal cross-sectional shape.

18. The display device of claim 16, wherein
the mesh portion of the first refractive layer has a mesh side wall facing the island portion of the first refractive layer,
the island portion of the first refractive layer has an island side wall facing the mesh portion of the first refractive layer, and
the opening of the first refractive layer is defined by the mesh side wall of the mesh portion and the island side wall of the island portion.

19. The display device of claim 18, wherein an upper edge of the mesh portion of the first refractive layer, defined as an edge where the upper surface of the mesh portion adjoins the mesh side wall of the mesh portion, surrounds the pixel opening in a plan view.

20. The display device of claim 18, wherein the emission layer overlaps all of the first portion of the pixel electrode, the second portion of the pixel electrode, and the third portion of the pixel electrode.
